(19) United States
(12) Patent Application Publication
(10) Pub. No.: US 2025/0349565 A1
(43) Pub. Date: Nov. 13, 2025

(54) SUBSTRATE SUPPORT HEAT TRANSFER STRUCTURES

(71) Applicant: Applied Materials, Inc., Santa Clara, CA (US)

(72) Inventor: Vijay D. PARKHE, San Jose, CA (US)

(21) Appl. No.: 19/195,829

(22) Filed: May 1, 2025

Related U.S. Application Data
(60) Provisional application No. 63/646,382, filed on May 13, 2024.

(51) Int. Cl. H01L 21/67; H01L 21/683

(52) U.S. Cl. CPC H01L 21/67103; H01L 21/6833; H01L 21/6838

(57) ABSTRACT

Embodiments of the disclosure include apparatus and methods for transferring heat between a substrate and a substrate support. The substrate support is disposed within a processing chamber. A heat exchanging element is disposed within the substrate support. A plurality of heat transfer structures extend from a surface of a substrate base of the substrate support. The heat transfer structures are configured to transfer heat between the substrate and the substrate support.

### CROSS-REFERENCE TO RELATED APPLICATIONS

This application claims priority to U.S. Provisional Patent Application Ser. No. 63/646,382 filed on May 13, 2024, which is herein incorporated by reference in its entirety.

### BACKGROUND

### Field

Embodiments described herein generally relate to systems and methods used in semiconductor device manufacturing. More specifically, embodiments of the present disclosure relate to methods and apparatus for transferring heat between a substrate and a substrate support.

### Description of the Related Art

In semiconductor device manufacturing applications, transferring heat between a substrate, or a “wafer,” and a substrate support facilitates improved control over aspects of deposition, etching, and other semiconductor processes. In order to transfer heat between the substrate and the substrate support, conventional systems primarily transfer heat generated by a heating element in a substrate support to one or more gases, and then transfer the heat from the one or more gases to a surface of the substrate. However, transferring heat to the substrate in this manner is inefficient because gases are relatively poor thermal conductors. Additionally, the gases are consumable which increases manufacturing costs.

Accordingly, there is a need in the art for a desirable substrate heating system that solves the problems described above.

### SUMMARY

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

Embodiments of the disclosure include apparatus and methods for transferring heat between a substrate and a substrate support. The substrate support is disposed within a processing chamber. A heat exchanging element is disposed within the substrate support. A plurality of heat transfer structures extend from a surface of a substrate base of the substrate support. The heat transfer structures are configured to transfer heat between the substrate and the substrate support.

Embodiments of the present disclosure provide an apparatus that includes a processing chamber. A substrate support is disposed within the processing chamber. A heating element is disposed within the substrate support. A plurality of heat transfer structures extend from a surface of the substrate support. The heat transfer structures are configured to transfer heat to a substrate.

Embodiments of the present disclosure provide a method that includes disposing a substrate over a plurality of heat transfer structures extending from a surface of a substrate base of a substrate support. At least some of the heat transfer structures are deformed by disposing the substrate over the plurality of heat transfer structures. Heat is transferred between a heat exchanging element of the substrate support and the substrate by at least one of the plurality of heat transfer structures.

### BRIEF DESCRIPTION OF THE DRAWINGS

So that the manner in which the above recited features of embodiments of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIGS. 1A, 1B, 1C, and 1D are schematic representations of an example substrate processing systems, in accordance with certain embodiments of the present disclosure.

FIGS. 2A, 2B, 20, 2D, and 2E are schematic representations of substrate support structures for transferring heat to a substrate that include a plurality of heat transfer structures, in accordance with certain embodiments of the present disclosure.

FIG. 3 illustrates schematic representations of a shape memory of a plurality of heat transfer structures, in accordance with certain embodiments of the present disclosure.

FIG. 4 is a process flow diagram illustrating a method for transferring heat to a substrate, in accordance with certain embodiments of the present disclosure.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments described herein generally relate to systems and methods for transferring heat between a substrate and a substrate support. More specifically, embodiments of the present disclosure relate to heat transfer structures for transferring heat between a substrate and a substrate support. In some embodiments, a processing chamber includes a substrate support that includes a plurality of heat transfer structures. One or more heat exchanging elements (e.g., resistive heating elements and/or heat exchanging fluid channels to heat or cool a substrate) are disposed within a substrate base of the substrate support.

In one or more embodiments, a plurality of heat transfer structures extend from a surface of the substrate base of the substrate support. The heat transfer structures are configured to efficiently transfer heat generated by the one or more heating elements disposed within the substrate base to a surface of the substrate. In some embodiments, the heat transfer structures include materials having relatively high thermal conductivity such as diamond, silver, copper and other thermally conductive materials. In some embodiments, the heat transfer structures can alternatively or additionally include materials such as conductive ceramic materials (e.g., BN, AlN, AlₓO_{y}), graphite, graphene, and other thermally conductive metal nitride or metal oxide materials.

In various embodiments, disposing the substrate over the heat transfer structures causes at least some of the heat transfer structures to deform to adapt to the shape of surface of a substrate due to the weight of the substrate and/or an external force provided to the substrate. Deforming the heat transfer structures is configured to increase a surface contact area between the substrate and the heat transfer structures, especially in cases where the substrate is non-flat due to, for example, intrinsic and extrinsic stresses formed in one or more portions of the substrate. In certain embodiments, heat is transferred between the substrate and the substrate support by at least some of the heat transfer structures. Heat is transferred more efficiently than by conventional systems that rely on gases to primarily transfer heat between the substrate and the substrate support.

### Processing System Examples

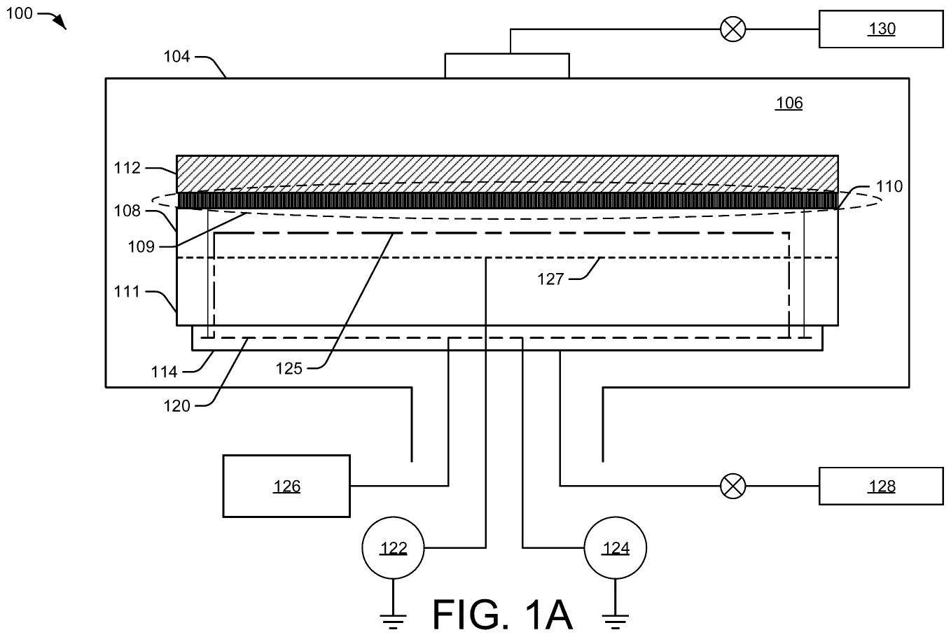

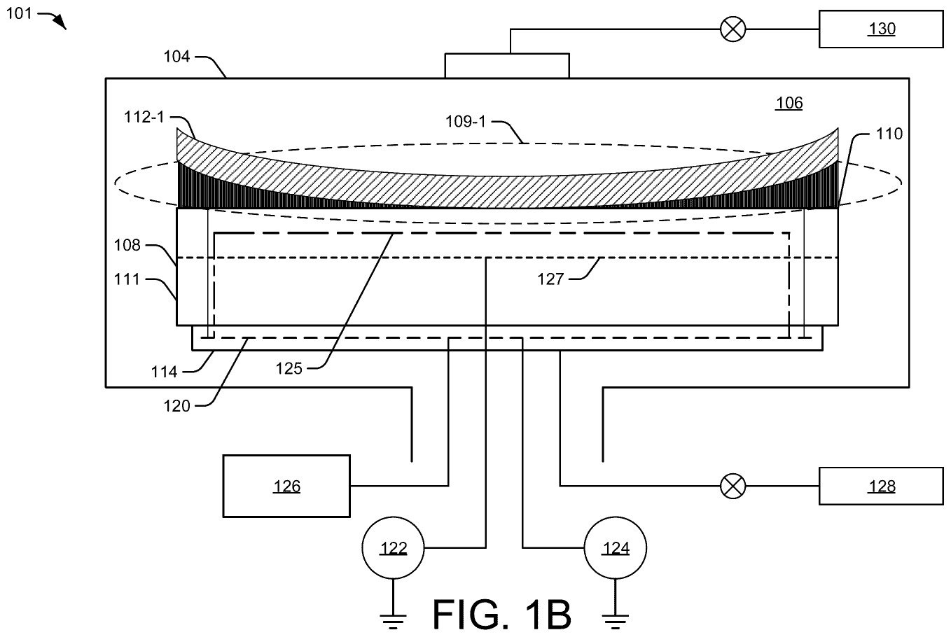

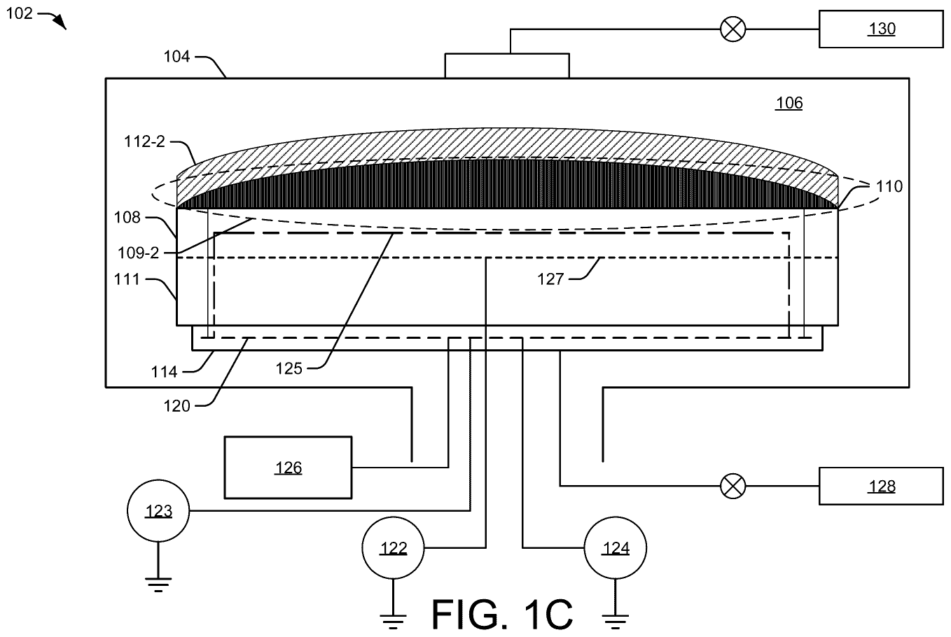

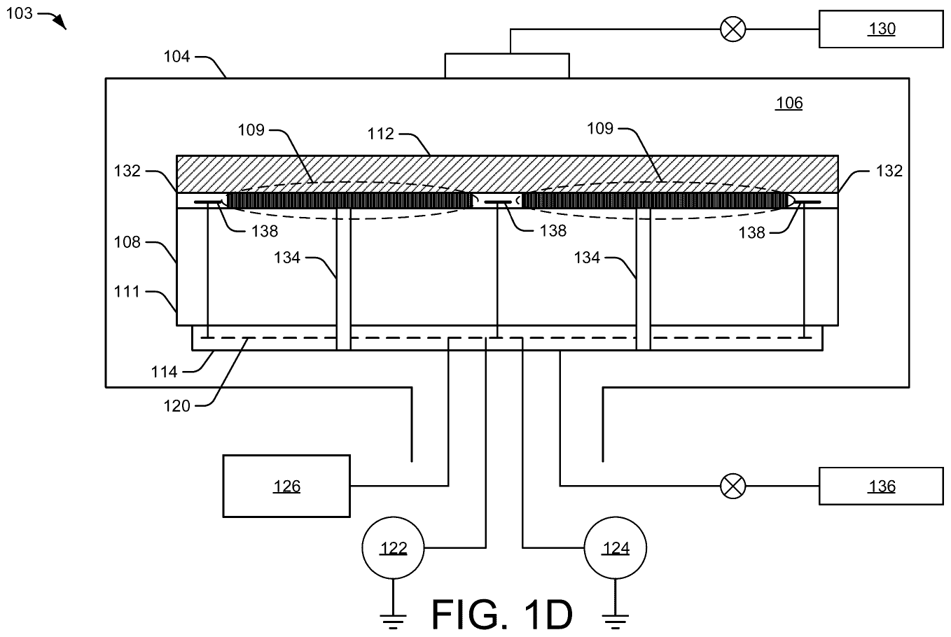

FIGS. 1A, 1B, 1C, and 1D are schematic representations of an example substrate processing systems 100, 101, 102, 103. FIG. 1A is a schematic representation of an example substrate processing system 100 for a flat substrate 112. The substrate processing system 100 includes a processing chamber 104. The processing chamber 104 is representative of a variety of different chambers including, without limitation, chemical vapor deposition (CVD) chambers, plasma vapor deposition (PVD) chambers, atomic layer deposition (ALD) chambers, etching chambers (including plasma-assisted systems and non-plasma-assisted systems), electron beam processing chambers, preclean chambers, thermal processing chambers, scanning electron microscope (SEM), or other similar processing systems or chambers. The processing chamber 104 contains a processing volume 106.

As shown in FIG. 1A, a substrate support 108 is disposed within the processing volume 106. The substrate support 108 includes a plurality of heat transfer structures 109 extending from a surface 110 of a substrate base 111 of the substrate support 108. In one or more embodiments, the heat transfer structures 109 include a layer of “pins” configured to support the substrate 112. In some examples, the heat transfer structures 109 have relatively high aspect ratios. In some embodiments, the heat transfer structures 109 include height to diameter ratios of greater than 5, such as 50. In some embodiments, the relatively high aspect ratios of the heat transfer structures 109 are configured to transfer thermal or electrical energy from the surface 110 of the substrate base 111 to the substrate 112. In various examples, the heat transfer structures 109 extend a distance of about 1 to about 5 millimeters from the surface 110, such as 2 millimeters from the surface 110. In various examples, the length of the heat transfer structures 109 is from about 1 to about 5 millimeters. In some embodiments, the substrate base 111 includes a block of a thermally conductive material, such as a metal or a ceramic material.

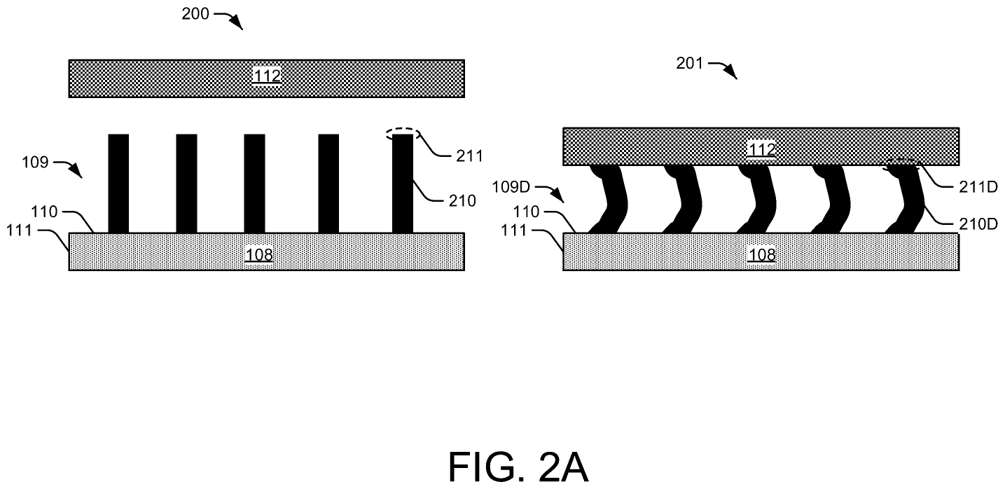

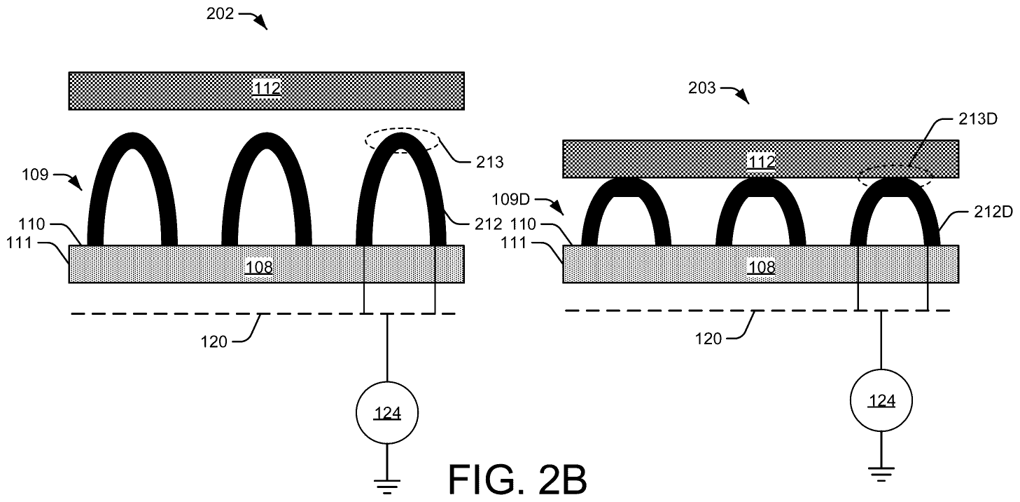

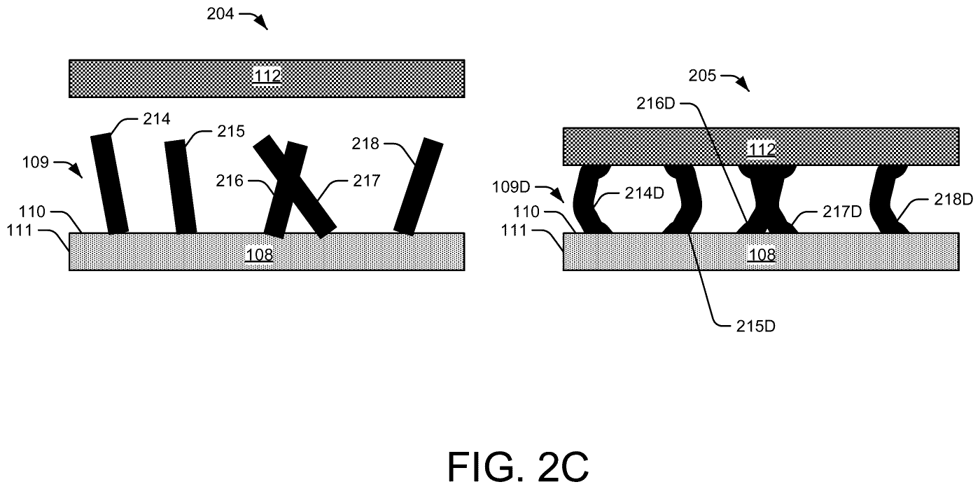

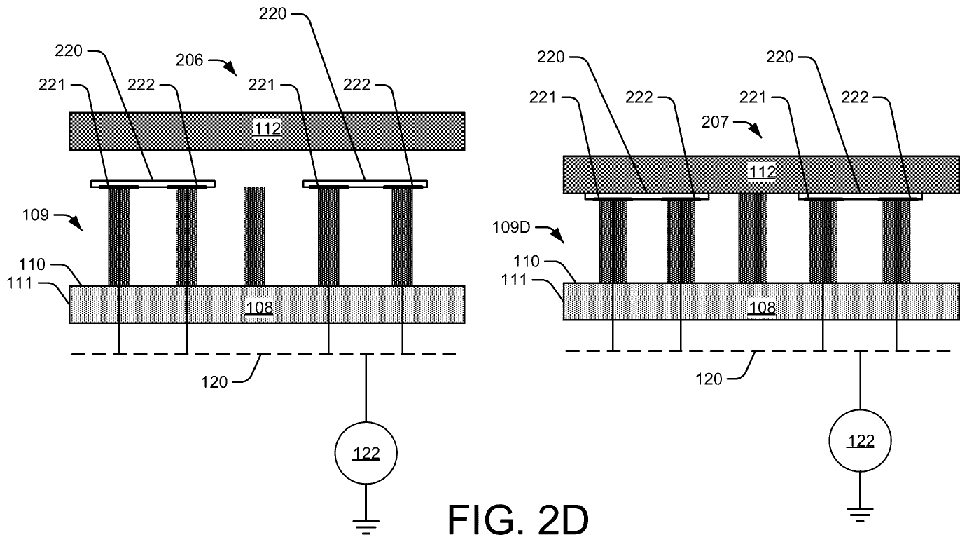

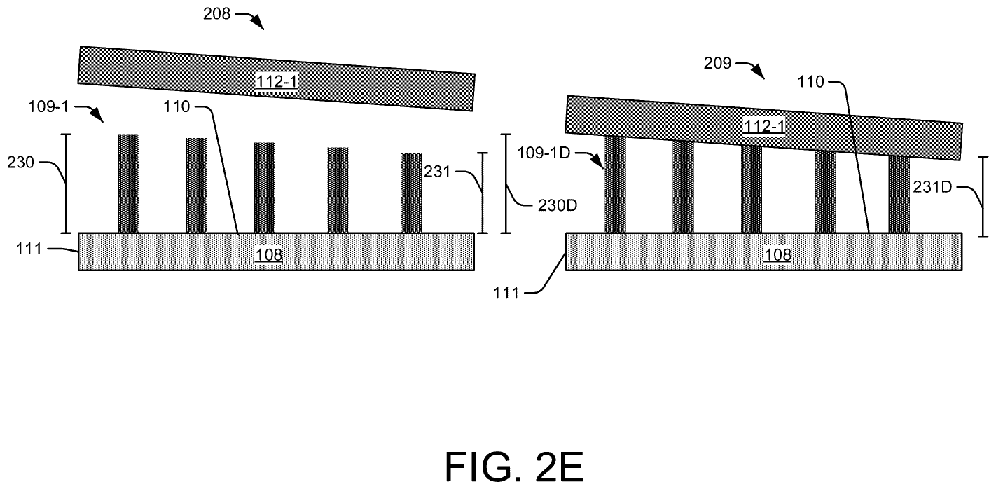

In some embodiments, the dimensions of the pins within the heat transfer structures 109, which include a length and an aspect ratio of each of the pins, is selected so that they will elastically deform when a substrate is positioned on the heat transfer structures 109 during processing. In some embodiments, the shape of one or more of the pins within the heat transfer structures 109 have a non-regular cross-sectional shape (e.g., hourglass shape) to allow each of the pins to deform in a known and repeatable manner as multiple different substrates are processed within a process chamber. In one embodiment, as illustrated in FIG. 2A and discussed further below, the pins of the heat transfer structures 109 are configured to buckle due to an applied axial load generated due to the presence of the substrate on the heat transfer structures 109. In some embodiments, the shape of one or more of the pins within the heat transfer structures 109 are non-linear (e.g., non-straight), as illustrated in FIG. 2B for example, to allow each of the pins to deform in a known and repeatable manner as multiple different substrates are processed within a process chamber.

In some embodiments, the heat transfer structures 109 are configured to transfer heat to the substrate 112 by thermal conduction. For example, the heat transfer structures 109 include thousands or millions of points of contact with the substrate 112. In one or more embodiments, the heat transfer structures 109 include one or more materials having a relatively high thermal conductivity. In some examples, the heat transfer structures 109 have a thermal conductivity in a range of 100 to 2000 watts per meter-kelvin (W/m-K). In other examples, the heat transfer structures 109 have a thermal conductivity of less than 100 W/m-K or greater than 2000 W/m-K.

In various embodiments, the heat transfer structures 109 include aluminum nitride, alumina, aluminum, silver, copper, gold, zinc, graphite, graphene, silicon carbide, tungsten, diamond-like carbon, or other materials having a relatively high thermal conductivity. In some embodiments, the heat transfer structures 109 include aluminum alloys, silver alloys, copper alloys, gold alloys, zinc alloys, tungsten alloys, or other metal alloys. In certain embodiments, the heat transfer structures 109 include ceramic materials such as ceramic fibers. In one or more embodiments, the heat transfer structures 109 include carbon nanotubes.

In various embodiments, disposing the substrate 112 over the heat transfer structures 109 may cause the heat transfer structures 109 to deform to the shape of the substrate. In some examples, a weight of the substrate 112 (e.g., about 200 g) may be configured to deform the heat transfer structures 109. In other examples, a weight may be applied to the substrate 112 to deform the heat transfer structures 109. In one example, a clamp ring (not shown) may be used to clamp the substrate 112 to the heat transfer structures 109 in order to urge a surface of the substrate to a surface of the heat transfer structures 109. In some embodiments, the elastically deformed heat transfer structures 109 increase a contact surface area between the substrate 112 and the heat transfer structures 109.

In some embodiments, a printed circuit board (PCB) 114 is disposed below the substrate support 108. In other embodiments, the PCB 114 may be disposed in different orientations relative to the substrate support 108. A direct current (“DC”) voltage source 122, a source radio frequency (RF) generator, and a heater power supply 124 (e.g., an alternating current (“AC”) source) are illustrated to be electrically coupled to a circuit layer 120 of the PCB 114. In some embodiments, the DC voltage source 122 is capable of outputting example voltages of +/−750 V, +/−1500 V, +/−3000 V, etc.

The substrate processing chamber 100 is illustrated to include a controller 126 which is communicatively coupled (e.g., electrically coupled) to the circuit layer 120 of the PCB 114. In some embodiments, the controller 126 includes a computing device having one or more processors, memory, and storage. The one or more processors can include central processing units, graphics processing units, accelerators, etc. The memory includes main memory for storing instructions for the one or more processors to execute or data for the one or more processors to operate on. For example, the memory includes random access memory (RAM). The storage includes mass storage for data or instructions. As an example and not by way of limitation, the storage may include a removable disk drive, flash memory, an optical disc, a magneto-optical disc, magnetic tape, or a Universal Serial Bus drive or two or more of these. The storage may include removable or fixed media and may be internal or external to the computing device. The storage may include any suitable form of non-volatile, solid-state memory, or read-only memory. The controller 126 includes a non-transitory computer readable medium or media. The non-transitory computer readable medium or media may include one or more semiconductor-based or other integrated circuits (ICs) (such, as for example, field-programmable gate arrays or application-specific ICs), hard disk drives, hybrid hard drives, optical discs, optical disc drives, magneto-optical discs, magneto-optical drives, solid-state drives, RAM drives, any other suitable non-transitory computer readable storage medium/media, or any suitable combination. The non-transitory computer readable medium or media may be volatile, non-volatile, or a combination of volatile and non-volatile.

The PCB 114 (e.g., the circuit layer 120) includes multiple transistors (e.g., MOSFETs) configured as switches. In some embodiments, the controller 126 is capable of controlling the transistors included in the PCB 114 to open or close electrical connections between the heater power supply 124 and a heating element 125 disposed within the substrate support 108. For example, the heating element 125 is a resistive heating element. Although one heating element 125 is illustrated in FIG. 1A, it is to be appreciated that multiple heating elements and/or heat exchanging channels (e.g., cooling channels) can be disposed within the substrate base 111 of the substrate support 108. The controller 126 controls the heater power supply 124 to cause the heating element 125 to generate heat which is transferred to the heat transfer structures 109. The heat transfer structures 109 transfer the heat generated by the heating element 125 to the substrate 112.

In some embodiments, the heating element 125 may be included in the heat transfer structures 109. For example, the heat transfer structures 109 can include one or more heating elements which are coated in materials having relatively high thermal conductivity and relatively low electrical conductivity. In one or more embodiments, the heat transfer structures 109 can include portions of the heating element 125 coated in diamond, diamond-like carbon, aluminum oxide, silicon dioxide, or other materials having relatively high thermal conductivity and relatively low electrical conductivity.

In some embodiments, the DC voltage source 122 is electrically coupled to a chucking electrode 127 disposed within the substrate base 111. In some other embodiments, the DC voltage source 122 is electrically coupled to a plurality of the heat transfer structures 109. In one or more examples, the one or more processors of the controller 126 execute instructions that cause the one or more processors to apply a DC bias to the chucking electrode 127 and/or the plurality of the heat transfer structures 109 using the DC voltage source 122. In these examples, the DC bias generates an electrostatic force configured to chuck the substrate 112 to the surface 110 and/or the heat transfer structures 109. In certain embodiments, the RF source generator 123 is coupled to an electrode (not shown) such that the RF source generator is capable of applying an RF bias to the substrate 112 via the electrode. In some embodiments, the DC voltage source 122 can apply a DC bias to the substrate 112 via the chucking electrode 127 and/or the plurality of the heat transfer structures 109.

The substrate processing chamber 100 is illustrated to include a vacuum source 128 in communication with the processing volume 106. In some embodiments, a vacuum pressure from the vacuum source 128 may be utilized to chuck the substrate 112 on the heat transfer structures 109 and/or the surface 110 of the substrate support 108. As shown in FIG. 1A, the substrate processing chamber 100 includes a gas delivery system 130, and the gas delivery system 130 is coupled to the processing volume 106. The gas delivery system 130 is configured to deliver at least one processing gas (e.g., argon, nitrogen, oxygen, hydrogen, etc.) to the processing volume 106. In examples in which the substrate processing chamber 100 includes a plasma-assisted system, the processing gas can include at least one of an inert gas (e.g., helium, argon, nitrogen (N₂)) or dry etching gas (e.g., HBr, HF, HCl, CF₄, NF₃ or XeF₂). In some embodiments, the gas delivery system 130 can include components for activating or energizing one or more processing gasses before delivering the processing gasses to the processing volume 106. In one or more embodiments, the gas delivery system 130 may be configured to provide backside gas to a plurality of ports formed within the substrate support 108. The backside gas and an edge seal band (not shown), in combination with the heat transfer structures 109, may be used to improve heat transfer between the surface 110 and the substrate 112.

FIG. 1B is a schematic representation of an example substrate processing system 101 for a convex substrate 112-1. The convex substrate 112-1 (a bowed substrate) is disposed over a plurality of heat transfer structures 109-1. In some embodiments, as discussed above, the heat transfer structures 109 are configured to elastically deform in order to conform to the shape of the convex substrate 112-1.

In other embodiments, unlike the heat transfer structures 109 which are configured to extend a uniform distance from the surface 110 of the substrate base 111, the heat transfer structures 109-1 extend different distances from the surface 110 in order to conform to the convex substrate 112-1. In an example, the heat transfer structures 109-1 include a layer of pins configured to support the convex substrate 112-1 without causing the convex substrate 112-1 to become more flat (e.g., un-deformed). In some examples, a first group of the heat transfer structures 109-1 extend a first distance from the surface 110 and a second group of the heat transfer structures 109-1 extend a second distance from the surface 110. The heat transfer structures 109-1 are configured to efficiently transfer heat generated by the heating element 125 to the convex substrate 112-1.

FIG. 1C is a schematic representation of an example substrate processing system 102 for a concave substrate 112-2 (a bowed substrate). The concave substrate 112-2 is disposed over a plurality of heat transfer structures 109-2. Similar to the heat transfer structures 109-1, the heat transfer structures 109-2 extend different distances from the surface 110 in order to conform to the concave substrate 112-2. In various embodiments, the heat transfer structures 109-2 include a fine layer of pins configured to support the concave substrate 112-2 without flattening the concave substrate 112-2. In some examples, a first group of the heat transfer structures 109-2 extend a first distance from the surface 110 and a second group of the heat transfer structures 109-2 extend a second distance from the surface 110. The heat transfer structures 109-2 are configured to efficiently transfer heat generated by the heating element 125 to the concave substrate 112-2.

FIG. 1D is a schematic representation of an example substrate processing system 103 where an interface between the substrate support 108 and the substrate 112 includes an edge seal 132. In the illustrate example, the substrate processing system 103 does not include the heating element 125; however, in other examples, the substrate processing system 103 includes the heating element 125. The substrate 112 is disposed over the heat transfer structures 109 which may cause the heat transfer structures 109 to deform. In some embodiments, the heat transfer structures 109 are configured to transfer heat from the substrate 112 and/or the substrate support 108 to reduce a temperature of the substrate 112 and/or the substrate support 108 (e.g., a temperature increased by plasma heating and/or biasing). In other embodiments, the heat transfer structures 109 are configured to transfer heat to the substrate 112 (e.g., from the heating element 125) to increase a temperature of the substrate 112.

In some embodiments, the substrate base 111 includes backside gas conduits 134 which are illustrated to be disposed below the heat transfer structures 109. The backside gas conduits 134 are in fluid communication with a backside gas system 136. In one or more embodiments, the backside gas system 136 is configured to deliver one or more backside gases to the substrate 112 via the backside gas conduits 134. In various embodiments, the substrate processing system 103 includes gas distribution devices (not shown) which are configured to uniformly distribute the one or more backside gases across the backside of the substrate 112.

In certain embodiments, the substrate base 111 includes pairs of electrodes 138 which are electrically coupled to the circuit layer 120. In some examples, the one or more processors of the controller 126 execute instructions that cause the one or more processors to apply a DC bias to the pairs of electrodes 138 by closing an electrical connection between the DC voltage source 122 and the pairs of electrodes 138. In one or more embodiments, the DC bias applied to the pairs of electrodes 138 generates an electrostatic force that chucks the substrate 112 to the surface 110 of the substrate base 111, deforms the heat transfer structures 109 to deform, increases a contact area between the substrate 112 and the heat transfer structures 109, reinforces the edge seal 132, etc. In some embodiments, applying the DC bias to the pairs of electrodes 138 may be configured to increase an efficiency of heat transfer from the substrate 112 to the heat transfer structures 109 or an efficiency of heat transfer from the heat transfer structures 109 to the substrate 112.

### Heat Transfer Structure Examples

FIGS. 2A, 2B, 20, 2D, and 2E are schematic representations of individual heat transfer structures that are configured for transferring heat between a substrate and the substrate support by use of a plurality of heat transfer structures. FIG. 2A illustrates a close-up view of a portion of a plurality of heat transfer structures, or a representation 200, before the substrate 112 is disposed over the heat transfer structures 109 (e.g., five pins). FIG. 2A also includes a close-up view of the portion of a plurality of heat transfer structures, or a representation 201, after the substrate 112 is disposed on the heat transfer structures 109D. In the representation 200, the heat transfer structures 109 extend straight from the surface 110 of the substrate base 111 of the substrate support 108 and a heat transfer structure 210 has a first upper surface area 211. In the representation 201, the substrate 112 causes the heat transfer structures 109D to become deformed due to the substrate's weight and/or an external force applied to the substrate 112. For example, the heat transfer structures 109D are deformed in response to a contact with the substrate 112. In some embodiments, the deformed heat transfer structure 210D has a second upper surface area 211D that is greater than the first upper surface area 211 due to the deformation of the contact surface. Notably, the second upper surface area 211D is a contact surface area with the substrate 112.

FIG. 2B illustrates a representation 202 before the substrate 112 is disposed over the heat transfer structures 109 and a representation 203 after the substrate 112 is disposed over the heat transfer structures 109D. In the representation 202, the heat transfer structures 109 are arch shaped such that a heat transfer structure 212 has two points of contact with the surface 110. The heat transfer structure 212 has a first upper surface area 213 in the representation 202. In the representation 203, the substrate 112 causes the heat transfer structures 109D to become deformed. A deformed heat transfer structure 212D has a second upper surface area 213. In some embodiments, the second upper surface area 213D is greater than the first upper surface area 213 and the second upper surface area 213D is a contact surface area with the substrate 112.

In some examples, the heat transfer structures 109 can include the heating element 125. For example, the heating element 125 can be disposed within the heat transfer structure 212 such that the two points of contact with the surface 110 include electrical connections to the heater power supply 124. In one or more embodiments, the heat transfer structure 212 includes a material disposed over the heating element 125. The material has relatively high thermal conductivity and relatively low electrical conductivity. In various examples, the heat transfer structure 212 can include the heating element 125 with the material disposed thereon including diamond, diamond-like carbon, aluminum oxide, silicon dioxide, or other materials having relatively high thermal conductivity and relatively low electrical conductivity.

FIG. 2C illustrates a representation 204 before the substrate 112 is disposed over the heat transfer structures 109 and a representation 205 after the substrate 112 is disposed over the heat transfer structures 109D. In the representation 204, the heat transfer structures 109 have different orientations relative to the surface 110. In some embodiments, the orientations of the heat transfer structures 109 may be random as a result of forming the heat transfer structures 109 using a deposition or growth process. In other embodiments, the orientations of the heat transfer structures 109 appear random based on a non-uniform crystalline structure of the heat transfer structures 109. In one or more embodiments, heat transfer structures 214-218 may be configured to efficiently transfer heat to the substrate 112, the convex substrate 112-1, and/or the concave substrate 112-2.

As shown in FIG. 2C, the heat transfer structure 214 has a first orientation relative to the surface 110, the heat transfer structure 215 has a second orientation relative to the surface 110, the heat transfer structure 216 has a third orientation relative to the surface 110, the heat transfer structure 217 has a fourth orientation relative to the surface 110, and the heat transfer structure 218 has a fifth orientation relative to the surface 110. In the representation 205, the substrate 112 causes the heat transfer structures 109D to become deformed. A deformed heat transfer structure 214D has a first deformed orientation relative to the substrate 112, a deformed heat transfer structure 215D has a second deformed orientation relative to the substrate 112, a deformed heat transfer structure 216D has a third deformed orientation relative to the substrate 112, a deformed heat transfer structure 217D has a fourth deformed orientation relative to the substrate 112, and a deformed heat transfer structure 218D has a sixth deformed orientation relative to the substrate 112.

FIG. 2D illustrates a representation 206 before the substrate 112 is chucked to the heat transfer structures 109 and a representation 207 after the substrate 112 is chucked to the heat transfer structures 109D. In one example, as shown in representation 206, a dielectric material 220 is disposed over pairs of conductive pins of the heat transfer structures 109. In some embodiments, a first heat transfer structure of the pair of heat transfer structures 109 includes a first electrode 221 and a second heat transfer structure of the pair of heat transfer structures 109 includes a second electrode 222. The first and second electrodes 221, 222 are coupled (e.g., electrically coupled) to the circuit layer 120. The DC voltage source 122 is also coupled (e.g., electrically coupled) to the circuit layer 120. In the representation 207, the substrate 112 causes the heat transfer structures 109D to become deformed. In various embodiments, the one or more processors of the controller 126 execute instructions that cause the one or more processors to deliver a DC bias from the DC voltage source 122 to the first and second electrodes 221, 222. The DC bias generates an electrostatic force which chucks the substrate 112 to the heat transfer structures 109D. One skilled in the art will appreciate that in some configurations the a dielectric material 220 can be disposed over an end surface (e.g., top surface) of each discrete conductive pin, rather than over pairs of pins, and thus allow each pin to be separately biased or biased in one or more groups of pins by the DC voltage source 122.

FIG. 2E illustrates a representation 208 before the convex substrate 112-1 is disposed over the heat transfer structures 109-1 and a representation 209 after the convex substrate 112-1 is disposed over the heat transfer structures 109-1D. In the representation 208, a first heat transfer structure extends a first distance 230 from the surface 110 of the substrate support 108 and a second heat transfer structure extends a second distance 231 from the surface 110 of the substrate support 108. In the representation 209, the convex substrate 112-1 causes the heat transfer structures 109-1D to become deformed. As shown in the representation 209, the first heat transfer structure extends a first deformed distance 230D from the surface 110 of the substrate support 108 and the second heat transfer structure extends a second deformed distance 231D from the surface 210 of the substrate support 108.

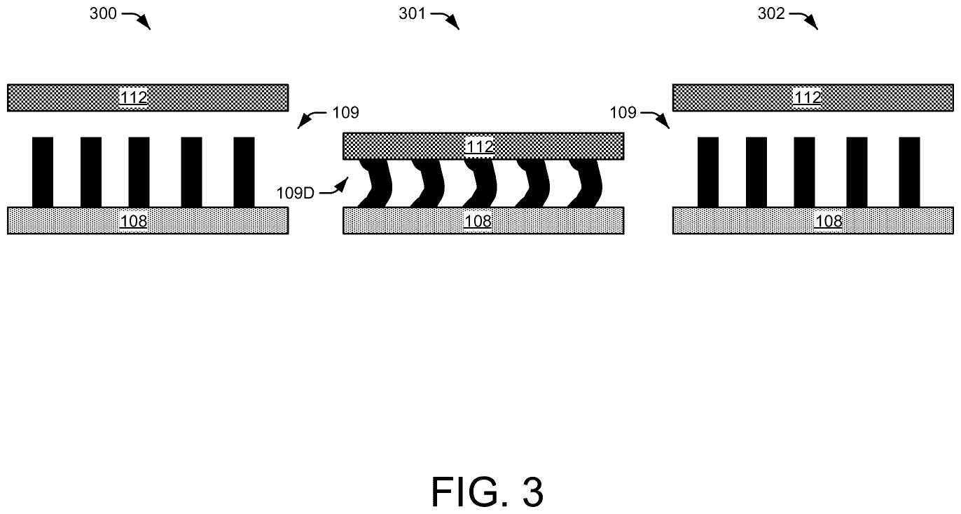

FIG. 3 illustrates schematic representations 300, 301, 302 of a shape memory of a plurality of heat transfer structures 109. In the representation 300, the substrate 112 is not disposed over the heat transfer structures 109 and the heat transfer structures 109 have an original shape. In the representation 301, the substrate 112 is disposed over the heat transfer structures 109D and the heat transfer structures 109D have a deformed shape. In the representation 302, the substrate 112 is no longer disposed over the heat transfer structures 109 and the heat transfer structures 109 have the original shape. Shape memory refers to the plurality of heat transfer structures 109 having a first original state at a first temperature and then the ability to be deformed at a second temperature, but return to the first original state at a third temperature. In some embodiments, the third temperature is greater than the second temperature. In some embodiments, the third temperature is the same as the first temperature.

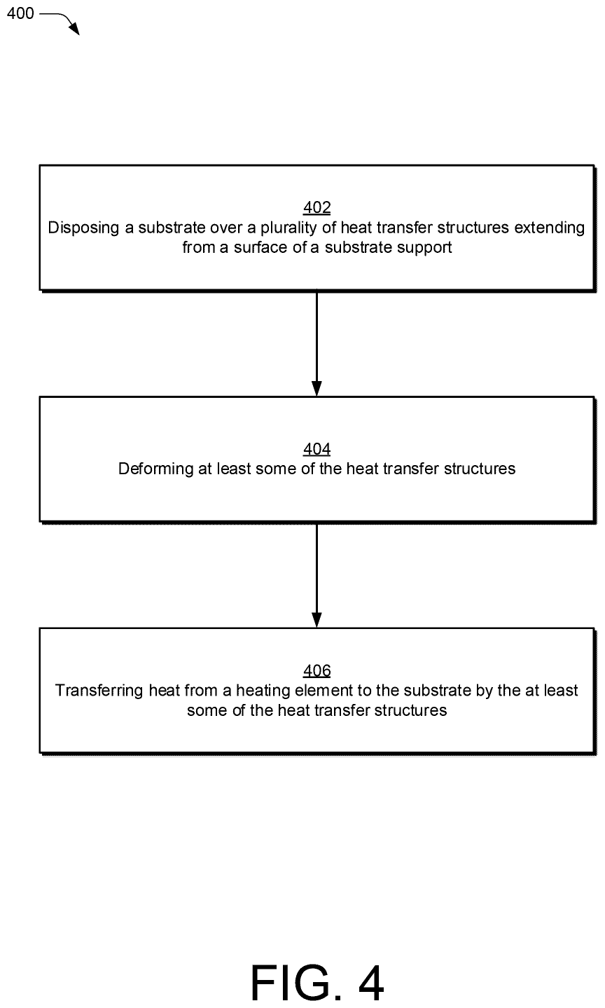

FIG. 4 is a process flow diagram illustrating a method 400 for transferring heat to a substrate. At operation 402, a substrate is disposed over a plurality of heat transfer structures extending from a surface of a substrate support. In some embodiments, the substrate 112 is disposed over the heat transfer structures 109 extending from the surface 110 of the substrate base 111 of the substrate support 108.

At operation 404, at least some of the heat transfer structures are deformed due to the presence of the substrate thereon. In one or more embodiments, the substrate 112 causes the heat transfer structures 109D to become deformed.

At operation 406, heat is transferred between a heat exchanging element within the substrate support and the substrate by the at least some of the heat transfer structures. In various embodiment, heat is transferred from the heating element 125 to the substrate 112 by the heat transfer structures 109D.

### Additional Considerations

In the above description, details are set forth by way of example to facilitate an understanding of the disclosed subject matter. It should be apparent to a person of ordinary skill in the field, however, that the disclosed implementations are exemplary and not exhaustive of all possible implementations. Thus, it should be understood that reference to the described examples is not intended to limit the scope of the disclosure. Any alterations and further modifications to the described devices, instruments, methods, and any further application of the principles of the present disclosure are fully contemplated as would normally occur to one skilled in the art to which the disclosure relates. In particular, it is fully contemplated that the features, components, and/or steps described with respect to one implementation may be combined with the features, components, and/or steps described with respect to other implementations of the present disclosure. As used herein, the term “about” may refer to a +/−10% variation from the nominal value. It is to be understood that such a variation can be included in any value provided herein.

As used herein, “a processor,” “at least one processor” or “one or more processors” generally refers to a single processor configured to perform one or multiple operations or multiple processors configured to collectively perform one or more operations. In the case of multiple processors, performance of the one or more operations could be divided amongst different processors, though one processor may perform multiple operations, and multiple processors could collectively perform a single operation. Similarly, “a memory,” “at least one memory” or “one or more memories” generally refers to a single memory configured to store data and/or instructions, multiple memories configured to collectively store data and/or instructions.

As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

While the foregoing is directed to embodiments of the present disclosure, other and further embodiments of the disclosure may be devised without departing from the basic scope thereof, and the scope thereof is determined by the claims that follow.

We claim:

1. An apparatus comprising:
a processing chamber;
a substrate support disposed within the processing chamber;
a heating element disposed within the substrate support; and
a plurality of heat transfer structures extending from a surface of the substrate support, the heat transfer structures configured to transfer heat to a substrate.

2. The apparatus of claim 1, wherein one or more of the heat transfer structures are configured to transfer the heat to the substrate from the heating element.

3. The apparatus of claim 1, wherein one or more of the heat transfer structures are configured to elastically deform in response to a contact with the substrate.

4. The apparatus of claim 1, wherein the one or more of the heat transfer structures are configured to increase a contact area with the substrate.

5. The apparatus of claim 1, wherein one or more of the heat transfer structures include electrodes coupled to a DC voltage source.

6. The apparatus of claim 5, wherein a DC voltage source is configured to apply a bias to a pair of electrodes that generates an electrostatic force configured to chuck the substrate.

7. The apparatus of claim 1, wherein one or more of the heat transfer structures includes at least one of aluminum nitride, aluminum, silver, copper, gold, zinc, graphite, graphene, silicon carbide, tungsten, or diamond-like carbon.

8. The apparatus of claim 1, wherein one or more of the heat transfer structures have a shape memory.

9. The apparatus of claim 1, wherein the substrate is bowed, a first group of the heat transfer structures extend a first distance from the surface of the substrate support, and a second group of the heat transfer structures extend a second distance from the surface of the substrate support.

10. The apparatus of claim 1, further comprising a vacuum source configured to generate a vacuum pressure to chuck the substrate against the heat transfer structures.

11. The apparatus of claim 1, wherein one or more of the heat transfer structures includes carbon nanotubes.

12. The apparatus of claim 1, wherein one or more of the heat transfer structures have a thermal conductivity in a range of 100 to 2000 watts per meter-kelvin.

13. The apparatus of claim 1, wherein the heat transfer structures comprise a plurality of pins that comprise a length to diameter ratio greater than 5, such as 50.

14. A method comprising:
disposing a substrate over a plurality of heat transfer structures extending from a surface of a substrate support;
deforming at least some of the heat transfer structures; and
transferring heat between a heat exchanging element of the substrate support and the substrate by use of one or more of the heat transfer structures.

15. The method of claim 14, wherein the one or more of the heat transfer structures are configured to transfer the heat to the substrate by thermal conduction.

16. The method of claim 14, wherein the one or more of the heat transfer structures have a thermal conductivity in a range of 100 to 2000 watts per meter-kelvin.

17. The method of claim 14, wherein the one or more of the heat transfer structures have a shape memory.

18. The method of claim 14, further comprising chucking the substrate by generating a vacuum pressure to vacuum chuck the substrate against the heat transfer structures.

19. The method of claim 14, further comprising chucking the substrate by generating an electrostatic force between the heat transfer structures and a surface of a substrate.

20. The method of claim 14, wherein the heat transfer structures comprise a plurality of pins that comprise a length to diameter ratio greater than 5, such as 50.
